(19) United States
(12) Patent Application Publication
(10) Pub. No.: US 2020/0041807 A1
(43) Pub. Date: Feb. 6, 2020

(54) LIGHT EMITTING DIODE DISPLAY WITH A MONOLITHIC WIRE-GRID POLARIZER FOR PRODUCING THREE-DIMENSIONAL IMAGES

(71) Applicant: CHRISTIE DIGITAL SYSTEMS USA, INC., Cypress, CA (US)

(72) Inventors: Darren PASTRIK, Kitchener (CA); Bryan HEMPHILL, Waterloo (CA); Marc LEMIEUX, Guelph (CA); Mark LAMM, Mississagua (CA)

(21) Appl. No.: 16/052,697

(22) Filed: Aug. 2, 2018

(51) Int. Cl. G02B 27/26; H01L 25/075; H01L 25/16; H01L 33/58; H04N 13/32; H04N 13/398

(52) U.S. Cl. CPC G02B 27/26; H01L 25/0753; H01L 25/167; G02B 5/3058; H04N 13/32; H04N 13/398; H01L 33/58

(57) ABSTRACT

A light emitting diode (LED) display is provided, including an array of LEDs comprising a first set of LEDs, and a second set of LEDs, alternating with the first set of LEDs, in a grid pattern. A driver drives the first and second set of LEDs according to, respectively, a first and second image. The display further includes a monolithic wire-grid polarizer, in front of the array, comprising first and second regions configured to respectively polarize light from the first and second set of LEDs, according to, respectively, a first linear polarization state and a second linear polarization state perpendicular to the first linear polarization state. The first and second regions are respectively aligned with the first and second sets of LEDs. A quarter-wave retarder is located in front of the wire-grid polarizer, for converting the first and second linear polarization states into respective circular polarization states.

### FIELD

The specification relates generally to light emitting diode displays, and specifically to a light emitting diode display with a monolithic wire-grid polarizer for producing three-dimensional images.

### BACKGROUND

Light emitting diode displays may be adapted to produce three-dimensional images by applying polymer film polarizers in front of a light emitting display, for example using strips of absorbing linear polarizers, however, such polymer film polarizers must be cut into pixel-wide strips and pixel-aligned horizontally, vertically or diagonally, which is a difficult and expensive process to achieve accurately and severely limits the amount of fill-factor-enhancing pixel diffusion that can be applied.

### BRIEF DESCRIPTIONS OF THE DRAWINGS

For a better understanding of the various embodiments described herein and to show more clearly how they may be carried into effect, reference will now be made, by way of example only, to the accompanying drawings in which:

FIG. 1 depicts a side schematic view of an example light emitting diode display according to the prior art.

FIG. 2 depicts a side schematic view of a light emitting diode display with a monolithic wire-grid polarizer for producing three-dimensional images, according to non-limiting examples.

FIG. 3 depicts a monolithic wire-grid polarizer for use in the light emitting diode display of FIG. 1, according to non-limiting examples.

FIG. 4 depicts the light emitting diode display of FIG. 1 in operation, according to non-limiting examples.

FIG. 5 depicts a schematic front view of the light emitting diode display of FIG. 1 showing pixel size relative to regions of a monolithic wire-grid polarizer, and circularly polarized light produced by each pixel, according to non-limiting examples.

### DETAILED DESCRIPTION

An aspect of the specification provides a light emitting diode (LED) display comprising: an array of LEDs comprising a first set of LEDs and a second set of LEDs alternating with the first set of LEDs in a grid pattern; a driver configured to: drive the first set of LEDs according to a first image; and drive the second set of LEDs according to a second image; a monolithic wire-grid polarizer located in front of the array of LEDs, the monolithic wire-grid polarizer comprising first regions configured to polarize light from the first set of LEDs according to a first linear polarization state and second regions configured to polarize light from the second set of LEDs according to a second linear polarization state perpendicular to the first linear polarization state, the first regions aligned with the first set of LEDs and the second regions aligned with the second set of LEDs; and a quarter-wave retarder located in front of the monolithic wire-grid polarizer, the quarter-wave retarder for converting the first linear polarization state and the second linear polarization state into respective circular polarization states.

Another aspect of the specification provides a wire-grid polarizer comprising: a single monolithic substrate, the single monolithic substrate being substantially transparent to light from light emitting diodes; a plurality of first regions on the single monolithic substrate configured to polarize the light according to a first linear polarization state; and a plurality of second regions on the single monolithic substrate configured to polarize the light according to a second linear polarization state perpendicular to the first linear polarization state, the plurality of first regions alternating with the plurality of second regions at the single monolithic substrate in a grid pattern.

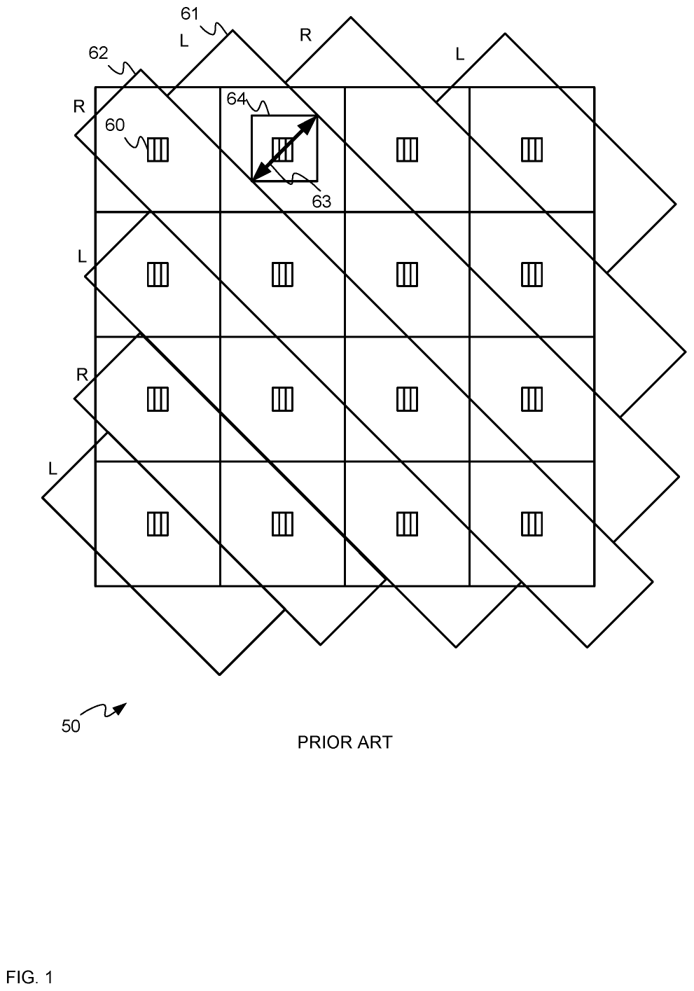

Attention is first directed to FIG. 1 which depicts an example light emitting diode (LED) display 50, adapted to show three-dimensional images, according to the prior art. In general, the LED display 50 comprise an array 60 of LEDs arranged in a grid, with alternating LEDs showing a left-eye image and a right-eye image. To polarize light from alternating LEDs, strips 61, 62 of polymer polarizer material are applied diagonally to the LED display 50, with strips 61 polarizing light from associated LEDs in a first direction (e.g. counterclockwise circularly polarized and/or for a right-eye image “R”) and diagonally alternating strips 52 polarizing light from associated LEDs in a second direction (e.g. clockwise circularly polarized and/or for a left-eye image “L”). As the strips 61, 62 are applied diagonally, the fill factor is limited by the diagonal distance 63 between the strips 61, 62 which limits pixel sizes to dimensions of a square 64, and the like, where the corner-to-corner distance is the diagonal distance 63 between the strips 61, 62. The square 64 may be achieved using a diffuser with limited diffusing properties.

To address this problem the strips 61, 62 may be replaced with squares of polymer, however the squares either need to be attached to the LED display 50 individually or bonded together, which can be expensive and time consuming. Alternatively, the strips 61, 62 may be applied in rows (e.g. vertically or horizontally), but this approach results in off-set left-eye and right-eye images.

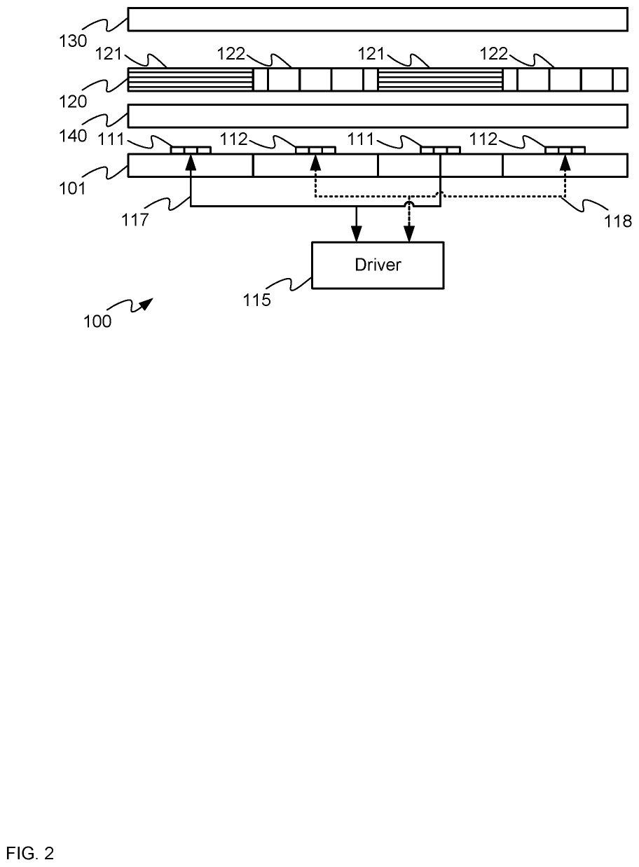

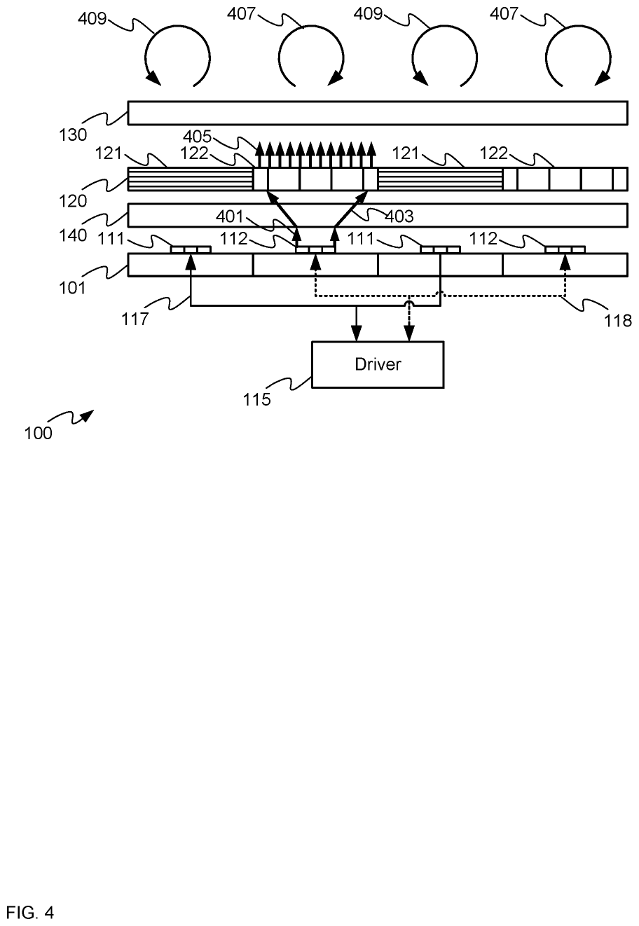

Attention is next directed to FIG. 2 which depicts a schematic side view of a light emitting diode (LED) display 100 that addresses the problem using a monolithic wire-grid polarizer described in more detail below. The LED display 100 comprises: an array 101 of LEDs comprising a first set 111 of LEDs and a second set 112 of LEDs alternating with the first set 111 of LEDs in a grid pattern (e.g. see FIG. 4); a driver 115 configured to: drive the first set 111 of LEDs according to a first image; and drive the second 112 set of LEDs according to a second image, the driver 115 respectively connected to the first set 111 of LEDs and the second set 112 of LEDs (using respective communication links 117, 118 each of which may include wireless and/or wired connections); a monolithic wire-grid polarizer 120 located in front of the array 101 of LEDs, the monolithic wire-grid polarizer 120 comprising first regions 121 configured to polarize light from the first set 111 of LEDs according to a first linear polarization state and second regions 122 configured to polarize light from the second set 112 of LEDs according to a second linear polarization state perpendicular to the first linear polarization state, the first regions 121 aligned with the first set 111 of LEDs and the second regions 122 aligned with the second set 112 of LEDs; and a quarter-wave retarder 130 located in front of the monolithic wire-grid polarizer 120, the quarter-wave retarder 130 for converting the first linear polarization state and the second linear polarization state into respective circular polarization states.

As depicted, the LED display 100 further comprises a diffuser 140 between the array 101 of LEDs and the monolithic wire-grid polarizer 120, the diffuser 140 configured to diffuse light from each of the first set 111 of LEDs and the second set 112 of LEDs to areas that are substantially similar to respective areas of the first regions 121 and the second regions 122 of the monolithic wire-grid polarizer 120. However, the diffuser 140 may be optional and/or a substrate of the monolithic wire-grid polarizer 120 may be adapted to diffuse light.

While the LED display 100 is depicted in a side view, with four pixels on the depicted side, (e.g. one pixel per set 111, 112 of LEDs) the LED display 100 may comprise any number of pixels, with regions 121, 122 of the monolithic wire-grid polarizer 120 alternatively aligned with pixels in the array 101. Indeed, as described below, the example array 101 includes sixteen sets 111, 112 of LEDs (e.g. the array 101 comprises a square array of LEDs, with four pixels and/or sets 111, 112 of LEDs to a side and/or eight sets 111 of LEDs for right-eye image and eight sets 112 of LEDs for a left eye image). However, the array 101 may comprise hundreds to thousands to millions of pixels and/or sets 111, 112 of LEDs.

Furthermore, while the array 101, the diffuser 140, the monolithic wire-grid polarizer 120 and the quarter-wave retarder 130 are depicted as being separated from one another for clarity, a person of skill in the art understands that the array 101, the diffuser 140, the monolithic wire-grid polarizer 120 and the quarter-wave retarder 130 are applied to one another using, for example, an optical adhesive and the like.

Each set 111, 112 of LEDs may comprise a respective set red, green and blue LEDs arranged on a sub-module, which may be arranged and or adapted to form modules of LEDs. However, any type of LED and/or color of LED is within the scope of the present specification.

The driver 115 generally comprises a hardware driver 115 including, but not limited to, one or more hardware processors, microprocessors and the like configured to drive the sets 111, 112 of LEDs to form a three-dimensional image (a data file for which may be stored in a memory (not depicted) and/or generated by an image generator and/or a content generator (not depicted).

Each of respective sets of LEDs in the first set 111 of LEDs and the second set 112 of LEDs represent respective pixels of a first image and a second image, which, together, form a three-dimensional image. For example, the first set 111 of LEDs may form a first image and/or a right eye image of a three-dimensional image, with light from the first set 111 of LEDs polarized in a first direction upon exiting the LED display 100 (e.g. counterclockwise circularly polarized); similarly, the second set 112 of LEDs may form a second image and/or a left eye image of the three-dimensional image, the light from the second set 112 of LEDs polarized in a second direction upon exiting the LED display 100 (e.g. clockwise circularly polarized). A viewer viewing the light from the LED display 100 through glasses with differently circularly polarized lenses will view right eye image with the right eye, and the left eye image with the left eye to view the three-dimensional image, presuming lenses of the glasses are adapted to transmit respective circularly polarized light of the right eye and left eye images. Such polarization is explained in further detail below.

While the diffuser 140 is optional, the diffuser 140 generally diffuses light from the sets 111, 112 of LEDs to an area that similar is to the areas of the regions 121, 122 of the monolithic wire-grid polarizer 120. Indeed, the diffuser 140 may be used to increase the fill factor of the pixels formed by the sets 111, 112 of LEDs as the monolithic wire-grid polarizer 120 is printed on one substrate, as described below, and is not applied to the LED display 100 in strips as generally occurs with prior art LED displays as depicted in FIG. 1.

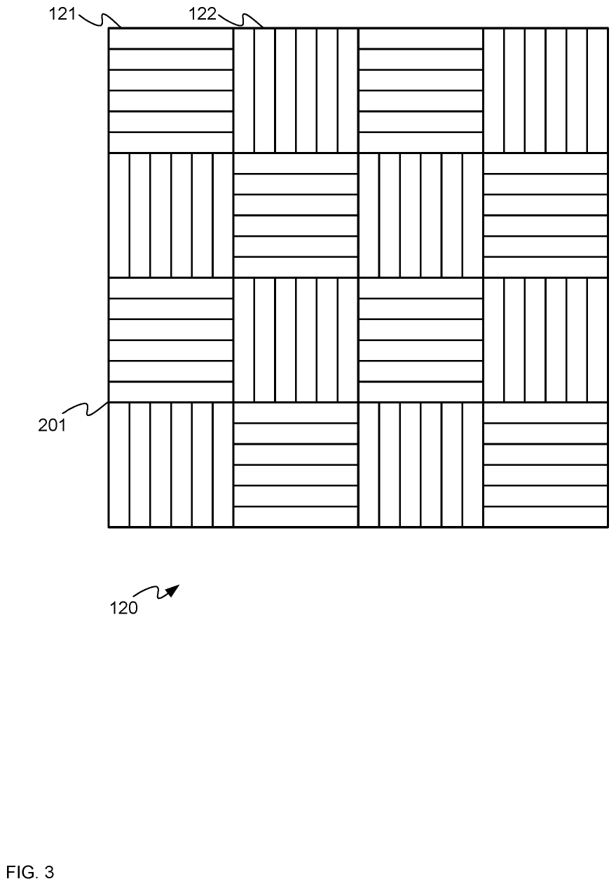

Indeed, attention is next directed to FIG. 3 which depicts a perspective view of the monolithic wire-grid polarizer 120 comprising a single monolithic substrate 201, the single monolithic substrate being substantially transparent to light from light emitting diodes (e.g. the sets 111, 112 of LEDs; the plurality of first regions 121 on the single monolithic substrate 201 configured to polarize the light according to a first linear polarization state; and the plurality of second regions 122 on the single monolithic substrate 201 configured to polarize the light according to a second linear polarization state perpendicular to the first linear polarization state, the plurality of first regions 121 alternating with the a plurality of second regions 122 at the single monolithic substrate 201 in a grid pattern.

The monolithic wire-grid polarizer 120 and/or the single monolithic substrate 201 comprises a plastic substrate, or the monolithic wire-grid polarizer 120 and/or the single monolithic substrate 2-1 comprises a glass substrate. Regardless, the single monolithic substrate 201 comprises a single piece of glass or plastic of a similar dimensions (e.g. size and shape other than thickness) as the array 101.

In general, the monolithic wire-grid polarizer 120 may be manufactured by printing the regions 121, 122 on the single monolithic substrate 201. In particular, wire-grid polarizers are generally made of very fine aluminum and/or metal wires (e.g. in a range of about 100 nm to 200 nm) printed onto glass or plastic (e.g. the single monolithic substrate 201) with a lithographic process.

As depicted, the regions 121 are linearly polarized horizontally (e.g. in a plane of FIG. 3) while the regions 122 are linearly polarized vertically (e.g. in a plane of FIG. 3). However, the regions 121, 122 may be linearly polarized in any direction as long as the respective linear polarizations of the regions 121, 122 are perpendicular and/or orthogonal to each other.

To construct the LED display 100, the diffuser 140 is applied to the array 101 of the sets 111, 112 of the LEDs, the monolithic wire-grid polarizer 120 is then applied to the diffuser 140 with the regions 121, 122 respectively aligned with the sets 111, 112 of LEDs, for example with respective centers of the regions 121, 122 aligned with the respective centers of the sets 111, 112 of LEDs. The quarter-wave retarder 130 is applied to the monolithic wire-grid polarizer 120. The array 101, the diffuser 140, the monolithic wire-grid polarizer 120 and the quarter-wave retarder 130 may be applied to one another using optical adhesive and the like. The quarter-wave retarder 130 generally converts the linearly polarized light from the regions 121, 122 to circularly polarized light

Attention is next directed to FIG. 4 which is substantially similar to FIG. 1 with like elements having like numbers. However, a path of light from one set 112 of LEDs is depicted. In particular, light 401 is emitted from a set 112 of LEDs, which is diffused 403 by the diffuser 140 to an area similar to the area of a respective region 122 of the monolithic wire-grid polarizer 120, which linearly polarizes 405 the light; the linearly polarized light from the region 122 is clockwise circularly polarized 407 by the quarter-wave retarder 130. While light 401 from only one set 112 of LEDs is depicted, it is understood that light from each set 111, 112 of LEDs follows a similar path, with a final circular polarization state determined by the respective polarization of the regions 121, 122 of the monolithic wire-grid polarizer 120, such that alternating sets 111, 112 of LEDs result in pixels alternating in circular polarization state. For example, as depicted, light from the first set 111 of LEDs is counterclockwise circularly polarized 409 and light from the second set 112 of LEDs is clockwise circularly polarized 407.

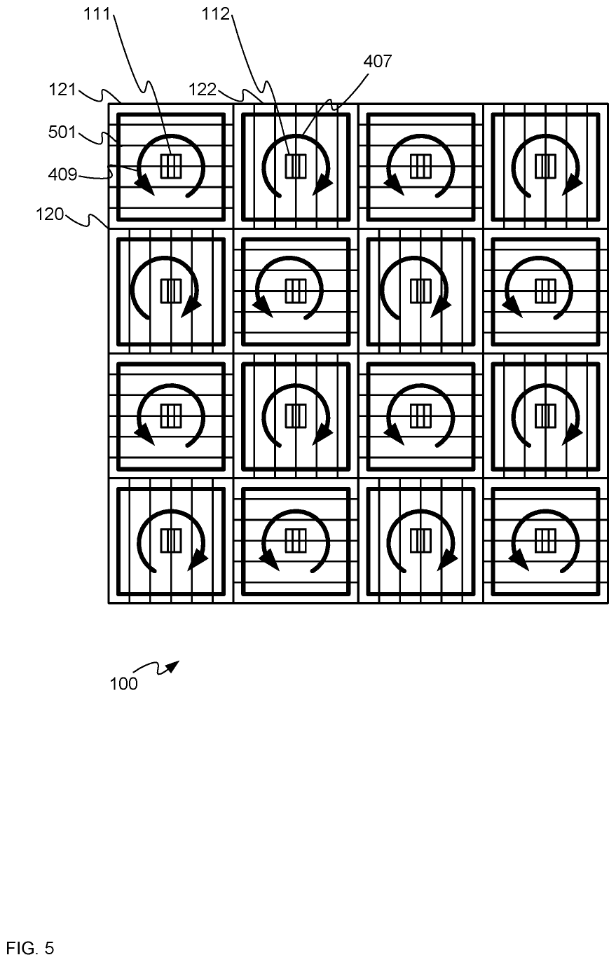

Attention is next directed to FIG. 5 which depicts a front view of the LED display 100 with the regions 121, 122 of the monolithic wire-grid polarizer 120 depicted in relation to the sets 111, 112 of LEDs, as well respective polarization states 407, 409 of the regions 121, 122. Also depicted are squares 501 showing a fill factor of the LED display 100 which are generally larger than the squares 64 of the prior art LED display 50 as use of the monolithic wire-grid polarizer 120 allows a respective shape of each of the regions 121, 122 to be matched to the respective shapes of the sets 111, 112 of the LEDs. For example, the squares 501 may be up to 95% of the size of each the regions 121, 122 depending on the properties of the diffuser 140.

Put another way, the respective regions 121, 122 may be produced on the monolithic substrate 201 using lithography to match a respective shape of the sets 111, 112 of LEDs. Hence, the monolithic wire-grid polarizer 120 may be aligned with the sets 111, 112 of LEDs with positional accuracy that may be better than using the strips 61, 62, as each strip 61, 62 must be aligned with LEDs as well as each other; use of the monolithic wire-grid polarizer 120 can also result in a cheaper process and/or a lowered failure rate as compared to use of the strips 61, 62.

Furthermore, while square pixels (e.g. squares 501) are depicted, the pixels of the LED display 100 may be any shape defined by a combination of the shape of the sets 111, 112 of the LEDs with the respective shapes of the regions 121, 122, including, but not limited to, rectangular shapes, circular shapes, polygonal shapes and the like.

While the LED display 100 is depicted as an array 101 of 16 pixels (e.g. with 8 pixels per left eye and right eye image), the LED display 100 may be any number of pixels according to the numbers of the sets 111, 112 of LEDs, with the monolithic wire-grid polarizer 120 adapted accordingly.

Hence, provided herein is an LED display for producing three-dimensional images that incorporates a monolithic wire-grid polarizer that can be simpler and less expensive than prior art LED displays, and which may result in improved fill-factors for pixels.

In this specification, elements may be described as “configured to” perform one or more functions or “configured for” such functions. In general, an element that is configured to perform or configured for performing a function is enabled to perform the function, or is suitable for performing the function, or is adapted to perform the function, or is operable to perform the function, or is otherwise capable of performing the function.

It is understood that for the purpose of this specification, language of “at least one of X, Y, and Z” and “one or more of X, Y and Z” can be construed as X only, Y only, Z only, or any combination of two or more items X, Y, and Z (e.g., XYZ, XY, YZ, XZ, and the like). Similar logic can be applied for two or more items in any occurrence of “at least one . . . ” and “one or more . . . ” language.

The terms “about”, “substantially”, “essentially”, “approximately”, and the like, are defined as being “close to”, for example as understood by persons of skill in the art. In some embodiments, the terms are understood to be “within 10%,” in other embodiments, “within 5%”, in yet further embodiments, “within 1%”, and in yet further embodiments “within 0.5%”.

Persons skilled in the art will appreciate that in some embodiments, the functionality of devices and/or methods and/or processes described herein can be implemented using pre-programmed hardware or firmware elements (e.g., application specific integrated circuits (ASICs), electrically erasable programmable read-only memories (EEPROMs), etc.), or other related components. In other embodiments, the functionality of the devices and/or methods and/or processes described herein can be achieved using a computing apparatus that has access to a code memory (not shown) which stores computer-readable program code for operation of the computing apparatus. The computer-readable program code could be stored on a computer readable storage medium which is fixed, tangible and readable directly by these components, (e.g., removable diskette, CD-ROM, ROM, fixed disk, USB drive). Furthermore, it is appreciated that the computer-readable program can be stored as a computer program product comprising a computer usable medium. Further, a persistent storage device can comprise the computer readable program code. It is yet further appreciated that the computer-readable program code and/or computer usable medium can comprise a non-transitory computer-readable program code and/or non-transitory computer usable medium. Alternatively, the computer-readable program code could be stored remotely but transmittable to these components via a modem or other interface device connected to a network (including, without limitation, the Internet) over a transmission medium. The transmission medium can be either a non-mobile medium (e.g., optical and/or digital and/or analog communications lines) or a mobile medium (e.g., microwave, infrared, free-space optical or other transmission schemes) or a combination thereof.

Persons skilled in the art will appreciate that there are yet more alternative embodiments and modifications possible, and that the above examples are only illustrations of one or more embodiments. The scope, therefore, is only to be limited by the claims appended hereto.

What is claimed is:

1. A light emitting diode (LED) display comprising:
an array of LEDs comprising a first set of LEDs and a second set of LEDs alternating with the first set of LEDs in a grid pattern;
a driver configured to: drive the first set of LEDs according to a first image; and drive the second set of LEDs according to a second image;
a monolithic wire-grid polarizer located in front of the array of LEDs, the monolithic wire-grid polarizer comprising first regions configured to polarize light from the first set of LEDs according to a first linear polarization state and second regions configured to polarize light from the second set of LEDs according to a second linear polarization state perpendicular to the first linear polarization state, the first regions aligned with the first set of LEDs and the second regions aligned with the second set of LEDs; and
a quarter-wave retarder located in front of the monolithic wire-grid polarizer, the quarter-wave retarder for converting the first linear polarization state and the second linear polarization state into respective circular polarization states.

2. The LED display of claim 1, wherein the monolithic wire-grid polarizer comprises a plastic substrate.

3. The LED display of claim 1, wherein the monolithic wire-grid polarizer comprises a glass substrate.

4. The LED display of claim 1, wherein the first image and the second image together form a three-dimensional image.

5. The LED display of claim 1, wherein each of respective sets of LEDs in the first set of LEDs and the second set of LEDs represent respective pixels of the first image and the second image.

6. The LED display of claim 5, further comprising a diffuser between the array of LEDs and the monolithic wire-grid polarizer, the diffuser configured to diffuse light from each of the first set LEDs and the second set of LEDs to areas that are substantially similar to respective areas of the first regions and the second regions of the monolithic wire-grid polarizer.

7. A wire-grid polarizer comprising:
a single monolithic substrate, the single monolithic substrate being substantially transparent to light from light emitting diodes;
a plurality of first regions on the single monolithic substrate configured to polarize the light according to a first linear polarization state; and
a plurality of second regions on the single monolithic substrate configured to polarize the light according to a second linear polarization state perpendicular to the first linear polarization state, the plurality of first regions alternating with the plurality of second regions at the single monolithic substrate in a grid pattern.

8. The wire-grid polarizer of claim 7, wherein the single monolithic substrate comprises a plastic substrate.

9. The wire-grid polarizer of claim 7, wherein the single monolithic substrate comprises a glass substrate.
